(19) United States
(12) Patent Application Publication
(10) Pub. No.: US 2024/0380183 A1
(43) Pub. Date: Nov. 14, 2024

(54) OPTICAL SEMICONDUCTOR DEVICE, OPTICAL INTEGRATED DEVICE, AND MANUFACTURING METHOD FOR OPTICAL SEMICONDUCTOR DEVICE

(71) Applicant: FURUKAWA ELECTRIC CO., LTD., Tokyo (JP)

(72) Inventors: Kenichi MIYAJIMA, Tokyo (JP); Kazuaki KIYOTA, Tokyo (JP); Tatsuya KIMOTO, Tokyo (JP); Akihiro IMAMURA, Chiba (JP); Koji HIRAIWA, Chiba (JP)

(73) Assignee: FURUKAWA ELECTRIC CO., LTD., Tokyo (JP)

(21) Appl. No.: 18/784,788

(22) Filed: Jul. 25, 2024

Related U.S. Application Data
(63) Continuation of application No. PCT/JP2023/000317, filed on Jan. 10, 2023.

(30) Foreign Application Priority Data
Jan. 31, 2022 (JP) 2022-013678

(51) Int. Cl. H01S 5/227; H01S 5/042

(52) U.S. Cl. CPC H01S 5/2275; H01S 5/04256

(57) ABSTRACT

An optical semiconductor device includes: a substrate; a first protrusion protruding from the substrate in a first direction and including a first mesa having a laminate structure in which a plurality of semiconductor layers are layered on the substrate in the first direction, the first mesa including an active layer as one of the semiconductor layers; and a second protrusion protruding from the substrate in the first direction at a distance from the first protrusion in a second direction intersecting with the first direction, the second protrusion having a same laminate structure as the laminate structure of the first mesa, wherein one of the plurality of semiconductor layers is exposed at an end portion of the second protrusion in the first direction.

This application is a continuation of International Application No. PCT/JP2023/000317, filed on Jan. 10,2023 which claims the benefit of priority of the prior Japanese Patent Application No. 2022-013678, filed on Jan. 31, 2022, the entire contents of which are incorporated herein by reference.

### BACKGROUND

The present disclosure relates to an optical semiconductor device, an optical integrated device, and a manufacturing method for the optical semiconductor device.

In the related art, an optical semiconductor device such as a semiconductor laser device or a semiconductor optical amplifier is known (for example, refer to International Laid-open Pamphlet No. 2021/024997). Moreover, in the related art, an optical integrated device is known that is configured by integrating an optical semiconductor device, such as the optical semiconductor device disclosed in International Laid-open Pamphlet No. 2021/024997, and a part including a waveguide (hereinafter, that part is referred to as an optical functional device) (for example, refer to Japanese Patent Application Laid-open No. 2017-092262).

### SUMMARY

In the known optical integrated devices, if there is a low level of alignment accuracy between the optical semiconductor device and the optical functional device, it leads to a decline in the coupling efficiency of the light between the optical semiconductor device and the optical functional device.

The optical semiconductor device disclosed in International Laid-open Pamphlet No. 2021/024997 includes a protrusion that functions as an alignment member with respect to the optical functional device in the layering direction. At the leading end of the protrusion, a passivation film is provided.

However, a passivation film is prone to have variation in the film thickness and is prone to getting peeled off. As a result, there is a risk that the alignment accuracy between the optical semiconductor device and the optical functional device becomes difficult to secure. In turn, there is a risk that the coupling efficiency of the light between the optical semiconductor device and the optical functional device becomes difficult to secure.

In the optical integrated device disclosed in Japanese Patent Application Laid-open No. 2017-092262, salient portions provided in the optical functional device are housed in depressed portions provided in the optical semiconductor device, and alignment in the layering direction is achieved between the salient portions and the depressed portions.

However, in a structure in which the salient portions are housed in the depressed portions, there is no other way but to form the depressed portions to be relatively greater in order to house the salient portions, thereby leading to a risk of an increase in the size of the optical semiconductor device and in turn an increase in the size of the optical integrated device.

In that regard, there is a need for a new and improved optical semiconductor device in which the alignment accuracy between the optical semiconductor device and an optical functional device in the layering direction of the semiconductor layers of the optical semiconductor device can be secured with more ease or with more reliability and a reduction in the size can be achieved; and to provide an optical integrated device and a manufacturing method for the optical semiconductor device.

According to one aspect of the present disclosure, there is provided an optical semiconductor device including: a substrate; a first protrusion protruding from the substrate in a first direction and including a first mesa having a laminate structure in which a plurality of semiconductor layers are layered on the substrate in the first direction, the first mesa including an active layer as one of the semiconductor layers; and a second protrusion protruding from the substrate in the first direction at a distance from the first protrusion in a second direction intersecting with the first direction, the second protrusion having a same laminate structure as the laminate structure of the first mesa, wherein one of the plurality of semiconductor layers is exposed at an end portion of the second protrusion in the first direction.

According to another aspect of the present disclosure, there is provided a manufacturing method for an optical semiconductor device, including: forming, on a substrate, a laminate structure in which a plurality of semiconductor layers are layered in a first direction, the plurality of semiconductor layers including a third semiconductor layer made of material functioning as an active layer, and an etch stop layer that is neither etchable by a predetermined etching solution nor etchable by a predetermined etching gas which are capable of etching other semiconductor layers, or having a sufficiently small etching rate than the other semiconductor layers, the etch stop layer being either a fourth semiconductor layer formed on an opposite side of the substrate with respect to the third semiconductor layer, or the third semiconductor layer; forming a plurality of mesas protruding from the substrate at a plurality of locations separated in a second direction intersecting with the first direction by partially removing the laminate structure on an opposite side of the substrate; forming a current inhibition layer in order to fill spaces among the plurality of mesas; forming a conductor layer on the opposite side of the substrate with respect to the third semiconductor layer; forming a first protrusion including a first mesa that is one of the plurality of mesas, a part of the current inhibition layer that is adjacent to the first mesa, and a part of the conductor layer that is present on an opposite side of the substrate with respect to the first mesa; and forming a second mesa that is one of the plurality of mesas other than the first mesa by performing etching using the predetermined etching solution or the predetermined etching gas such that the etch stop layer included in the second mesa becomes exposed at an end portion in the first direction.

### BRIEF DESCRIPTION OF THE DRAWINGS

FIG. 1 is an exemplary and schematic cross-sectional view of an optical semiconductor device according to a first embodiment;

FIG. 2 is an exemplary and schematic planar view of the optical semiconductor device according to the first embodiment;

FIG. 3 is an exemplary and schematic cross-sectional view of an optical integrated device according to the first embodiment;

FIG. 4 is an exemplary and schematic side view of the optical integrated device according to the first embodiment;

FIG. 5 is an exemplary and schematic cross-sectional view of an intermediate product material obtained during the process of manufacturing the optical semiconductor device according to the first embodiment;

FIG. 6 is an exemplary and schematic cross-sectional view of an intermediate product material obtained at a later stage than the stage illustrated in FIG. 5 during the process of manufacturing the optical semiconductor device according to the first embodiment;

FIG. 7 is an exemplary and schematic cross-sectional view of an intermediate product material obtained at a later stage than the stage illustrated in FIG. 6 during the process of manufacturing the optical semiconductor device according to the first embodiment;

FIG. 8 is an exemplary and schematic cross-sectional view of an intermediate product material obtained at the same stage as the stage illustrated in FIG. 7 during the process of manufacturing the optical semiconductor device according to the first embodiment;

FIG. 9 is an exemplary and schematic cross-sectional view of an intermediate product material obtained at a later stage than the stage illustrated in FIGS. 7 and 8 during the process of manufacturing the optical semiconductor device according to the first embodiment;

FIG. 10 is an exemplary and schematic cross-sectional view of an intermediate product material obtained at a later stage than the stage illustrated in FIG. 9 during the process of manufacturing the optical semiconductor device according to the first embodiment;

FIG. 11 is an exemplary and schematic cross-sectional view of an intermediate product material obtained at a later stage than the stage illustrated in FIG. 10 during the process of manufacturing the optical semiconductor device according to the first embodiment;

FIG. 12 is an exemplary and schematic cross-sectional view of an optical semiconductor device according to a second embodiment;

FIG. 13 is an exemplary and schematic cross-sectional view of an optical semiconductor device according to a third embodiment; and

FIG. 14 is an exemplary and schematic planar view of an optical semiconductor device according to a fourth embodiment.

### DETAILED DESCRIPTION

Exemplary embodiments are described below. The configurations explained in the embodiments described below as well as the actions and the results (effects) attributed to the configurations are only exemplary. Thus, the present disclosure can be implemented also using some different configuration than the configurations disclosed in the embodiments described below. Meanwhile, according to the present disclosure, it becomes possible to achieve at least one of various effects (including secondary effects) that are attributed to the configurations.

The embodiments described below include identical constituent elements. Thus, based on the identical configuration according to each embodiment, it becomes possible to achieve identical actions and identical effects. In the following explanation, the identical constituent elements are referred to by the same reference numerals, and their explanation is not given in a repeated manner.

In the present written description, ordinal numbers are assigned only for convenience and with the aim of differentiating among the directions and among the parts. Thus, the ordinal numbers do not indicate the priority or the sequencing.

In the drawings, the X direction is indicated by an arrow X, the Y direction is indicated by an arrow Y, and the Z direction is indicated by an arrow Z. The X direction, the Y direction, and the Z direction intersect with each other and are orthogonal to each other. In the following explanation, the X direction is referred to as the longitudinal direction or the extension direction, the Y direction is referred to as the short direction or the width direction, and the Z direction is referred to as the layering direction or the height direction.

Meanwhile, the drawings are schematic diagrams intended for use in the explanation. Thus, in the drawings, the scale and the ratio in the vertical and horizontal directions does not necessarily match with the actual objects.

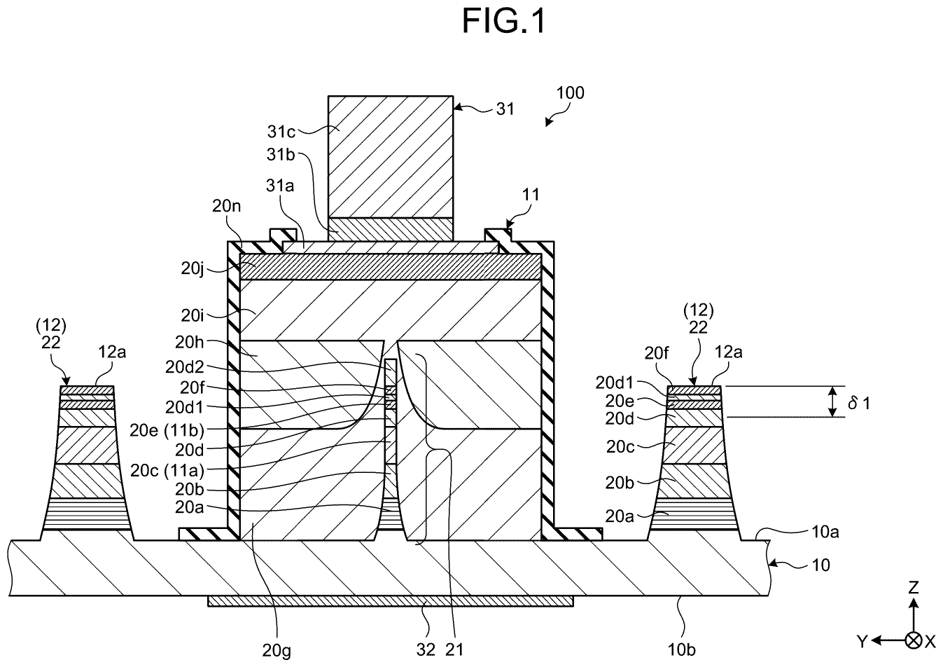

FIG. 1 is a cross-sectional view of an optical semiconductor device 100 according to a first embodiment. As illustrated in FIG. 1, the optical semiconductor device 100 includes a substrate 10, a first protrusion 11, and two second protrusions 12.

The substrate 10 has a substantially constant thickness in the Z direction, and expands across the Z direction. The substrate 10 has faces 10a and 10b. The face 10a is facing toward the Z direction and intersects with the Z direction. The face 10b is positioned on the opposite side of the face 10a, is facing toward the opposite direction of the Z direction, and intersects with the Z direction. The substrate 10 is, for example, made of n-InP.

The first protrusion 11 protrudes in the Z direction from the face 10a of the substrate 10. The two second protrusions 12 also protrude in the Z direction from the face 10a. Of the two second protrusions 12, one second protrusion 12 is positioned at a distance from the first protrusion 11 in the Y direction, and the other second protrusion 12 is positioned at a distance from the first protrusion 11 in the opposite direction of the Y direction. Thus, the first protrusion 11 is positioned in between the two second protrusions 12. Herein, the Z direction represents an example of a first direction, and the Y direction represents an example of a second direction. In the first embodiment, although two second protrusions 12 are included, it is also possible to include a single second protrusion 12 or to include three or more second protrusions 12. When three or more second protrusions 12 are included, the first protrusion 11 can be positioned in between the three or more second protrusions 12.

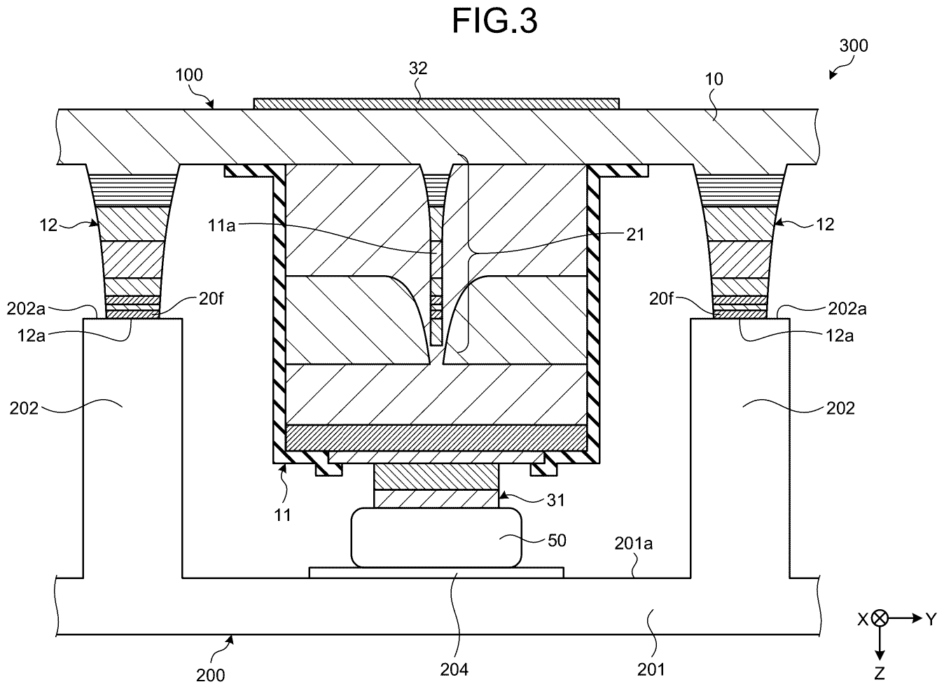

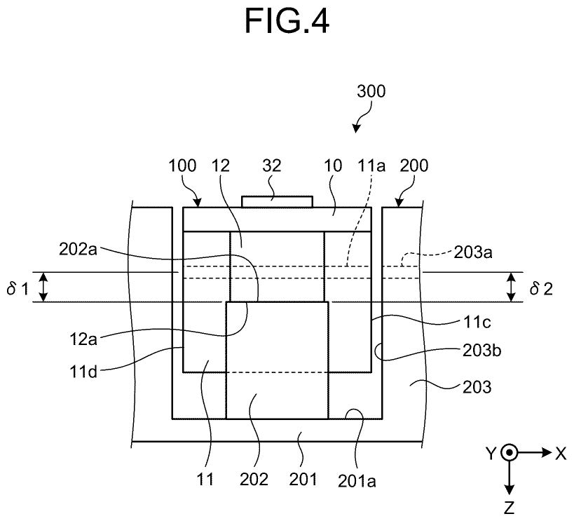

The first protrusion 11 represents, for example, the part functioning as a laser emission device of a known type; and can also be referred to as a functional unit. The second protrusions 12 represent, for example, the parts used for ensuring alignment between the optical semiconductor device 100 and an optical functional device 200 (see FIGS. 3 and 4) in the Z direction, and can be referred to as alignment members. In each second protrusion 12, an end portion 12a in the Z direction serves as the contact portion with respect to the optical functional device 200. The end portion 12a of each second protrusion 12 is a planar surface facing toward the Z direction and intersecting with the Z direction. The end portion 12a can also be referred to as an end face or a contact face.

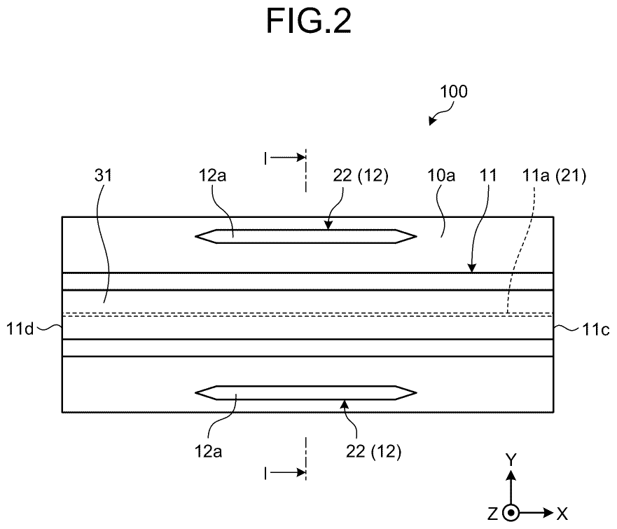

FIG. 2 is a planar view of the optical semiconductor device 100. As illustrated in FIG. 2, the first protrusion 11 and the second protrusions 12 extend on the substrate 10 in the X direction. Meanwhile, FIG. 1 is a cross-sectional view of the optical semiconductor device 100 at an I-I position illustrated in FIG. 2. In the cross-sectional shape illustrated in FIG. 1, the first protrusion 11 and the second protrusions 12 extend in the X direction while having the width in the Y direction and having the height in the Z direction. The first protrusion 11 extends in between an end face 11c of the optical semiconductor device 100 in the X direction and an end face 11d of the optical semiconductor device 100 in the opposite direction of the X direction. Each second protrusion 12 extends for a predetermined length in the substantially central portion in the X direction of the optical semiconductor device 100. The length of each second protrusion 12 in the X direction is substantially half the length of the optical semiconductor device 100 and the first protrusion 11 in the X direction. However, that is not the only possible case. It is desirable that the length of each second protrusion 12 in the X direction is equal to or greater than one-third of the length of the optical semiconductor device 100 and the first protrusion 11 in the X direction.

As illustrated in FIG. 1, the first protrusion 11 includes a mesa 21, and each second protrusion 12 includes a mesa 22. The mesa 21 represents an example of a first mesa, and each mesa 22 represents an example of a second mesa.

The mesa 21 and the mesas 22 are manufactured according the same semiconductor process. Thus, the mesa 21 as well as each mesa 22 includes a plurality of same semiconductor layers (a first layer 20a to a sixth layer 20f) in a layered form, and partially has the same laminate structure. That is, the same semiconductor layers included in the mesas 21 and 22 are made of the same material. Moreover, the semiconductor layers are arranged in the Y direction, and have the same positions in the Z direction with respect to the face 10a of the substrate 10. However, in each mesa 22, the end portion in the Z direction is removed by means of etching. Hence, the end portion in the Z direction of the mesa 21 includes a semiconductor layer (a layer 20d2 that is farthest from the substrate 10) that is not included in the mesas 22. More particularly, the mesa 21 as well as each mesa 22 includes the first layer 20a, the second layer 20b, the third layer 20c, the fourth layer 20d, the fifth layer 20e, a layer 20d1, and the sixth layer 20f that are layered on the face 10a of the substrate 10 in the Z direction. Moreover, in the mesa 21, the layer 20d2 is further included on top of the sixth layer 20f, that is, on the opposite side of the substrate 10 with respect to the sixth layer 20f.

The first layer 20a has a laminate structure including, for example, n-InP and n-InGaAsP. In the mesa 21, the first layer 20a functions as the buffer layer. The second layer 20b is made of n-InP and, in the mesa 21, functions as the cladding layer. Meanwhile, in the mesa 21, the first layer 20a and the second layer 20b can be combinedly referred to as the cladding layer.

The third layer 20c has a laminate structure including n-InGaAsP. In the mesa 21, the third layer 20c operates as an active layer 11a.

The fourth layer 20d is, for example, made of p-InP. The fifth layer 20e includes, for example, first parts that are arranged at regular intervals in the X direction and that are made of p-InGaAsP; and second parts that fill the gaps between the neighboring first parts in the X direction and that are made of p-InP. In the mesa 21, the fifth layer 20e functions as a diffraction grating layer 11b. On the opposite side of the substrate 10 with respect to the fifth layer 20e, the layer 20d1 is formed that is made of the same material as the fourth layer 20d. Thus, the fifth layer 20e is sandwiched between the fourth layer 20d and the layer 20d1.

The sixth layer 20f is, for example, made of p-InGaAsP. The sixth layer 20f is, what is called, a quaternary layer and has the property of neither being etchable by a predetermined etching solution (for example, hydrochloric acid) nor being etchable by a predetermined etching gas (for example, a mixed gas of methane and hydrogen) usable in the etching of other semiconductor layers (for example, the cladding layer made of InP); or has the property of having a sufficiently small ratio of the etching rate (for example, 1/10 or lower) as against the etching rate of the other semiconductor layers. Herein, the sixth layer 20f can also be referred to as an etch stop layer.

In the mesa 21, the sixth layer 20f is positioned on the opposite side of the substrate 10 with respect to the third layer 20c that functions as the active layer 11a.

The mesa 22 constitutes each second protrusion 12. The sixth layer 20f is exposed at the end portion in the Z direction of each mesa 22, that is, each second protrusion 12; and constitutes the end portion 12a. As is clear from FIG. 1, in the first embodiment, on the sixth layer 20f of each second protrusion 12, no other layer such as a passivation film is formed. In the first embodiment, the sixth layer 20f of the mesa 21 represents an example of a first semiconductor layer, and the sixth layer 20f of each mesa 22 represents an example of a second semiconductor layer.

In the mesa 21, on the opposite side of the substrate 10 with respect to the sixth layer 20f, the layer 20d2 is formed with the same material as the fourth layer 20d.

In the first protrusion 11, the mesa 21 is enclosed by current inhibition layers 20g and 20h that are placed adjacent in the Y direction and in the opposite direction of the Y direction; and is enclosed by a cladding layer 20i that is placed adjacent in the Z direction. The current inhibition layer 20g is, for example, made of p-InP; and the current inhibition layer 20h is, for example, made of n-InP. The cladding layer 20i is, for example, made of p-InP.

On the opposite side of the substrate 10 with respect to the cladding layer 20i, a contact layer 20j is formed. The contact layer 20j is, for example, made of p-InGaAsP. On the contact layer 20j, an electrode 31 is disposed. The electrode 31 is a P-side electrode that is positioned at a distance from the active layer 11a in the Z direction. For example, the electrode 31 includes a base layer 31a, a barrier layer 31b, and a thick-film layer 31c that are layered on the contact layer 20j in the Z direction. The base layer 31a has, for example, a laminate structure that includes Au and AuZn. The barrier layer 31b includes, for example, Pt. The thick-film layer 31c includes, for example, Au. Herein, the electrode 31 represents an example of a first electrode.

In the first protrusion 11, the lateral face in the Y direction and the lateral face in the opposite direction of the Y direction are covered by an insulating film 20n. The insulating film 20n is, for example, made of SiN.

On the face 10b of the substrate 10, an electrode 32 is disposed. The electrode 32 is an N-side electrode having, for example, a laminate structure including AuGe, Ni, and Au.

FIG. 3 is a cross-sectional view of an optical integrated device 300 that includes the optical semiconductor device 100 illustrated in FIGS. 1 and 2 according to the first embodiment and includes the optical functional device 200. As illustrated in FIG. 3, in the optical integrated device 300, the optical semiconductor device 100 and the optical functional device 200 are overlapping in the Z direction. Herein, the optical functional device 200 can also be referred to as a silicon platform. In FIG. 3 is illustrated the state in which the optical semiconductor device 100 and the optical functional device 200 are aligned.

The optical functional device 200 includes a base 201, protrusions 202, and an electrode 204. The base 201 has a substantially constant thickness in the Z direction, and expands across the Z direction. Moreover, the base 201 has a face 201a that is facing toward the opposite direction of the Z direction and is intersecting with the Z direction.

The protrusions 202 protrude from the face 201a in the opposite direction of the Z direction. The protrusions 202 are arranged in the Z direction with respect to the second protrusions 12 of the optical semiconductor device 100, and are disposed to abut against the second protrusions 12 in the Z direction. In the first embodiment, the optical functional device 200 includes two protrusions 202 corresponding to the two second protrusions 12. Regarding the protrusions 202, the length in the X direction and the width in the Y direction is set according to the second protrusions 12. In the first embodiment, the length of the protrusions 202 in the X direction is greater than the length of the second protrusions 12 in the X direction, and the width of the protrusions 202 in the Y direction is greater than the width of the second protrusions 12 in the Y direction. However, that is not the only possible case.

The end portion 12a in the Z direction of each second protrusion 12 of the optical semiconductor device 100 comes in contact with an end portion 202a in the opposite direction of the Z direction of the corresponding protrusion 202 of the optical functional device 200. As a result, the optical semiconductor device 100 and the optical functional device 200 get aligned in the z direction. In the aligned state, the end portion 202a is positioned on the opposite side of the substrate 10 with respect to the corresponding second protrusion 12 of the optical semiconductor device 100, and makes contact with the end portion 12a of the corresponding second protrusion 12. Herein, the end portions 202a represents examples of a contact portion, and the protrusions 202 represent examples of a third protrusion.

The electrode 204 is disposed on the face 201a and, in the Z direction, is facing toward the electrode 31 of the optical semiconductor device 100 with a space (not illustrated) left therebetween. The electrodes 31 and 204 are, for example, electrically connected to each other via a junction 50 such as an AuSn solder bump. In the first embodiment, the optical functional device 200 includes the base 201, and includes the protrusions 202 that protrude from the base 201 in the opposite direction of the Z direction. Thus, in between the base 201 and the first protrusion 11 of the optical semiconductor device 100, it is possible to provide a part in which the electrodes 31 and 204 are electrically connected to each other via the junction 50. With such a configuration, the distance between the electrodes 31 and 204 can be shortened, and the electrical resistance therebetween can be lowered. Herein, the electrode 204 represents an example of a second electrode.

FIG. 4 is a side view of some part of the optical integrated device 300, which includes the optical semiconductor device 100 illustrated in FIGS. 1 and 2 according to the first embodiment and includes the optical functional device 200.

As illustrated in FIG. 4, the optical functional device 200 includes a body 203. Inside the body 203, an optical waveguide is disposed that includes a core 203a extending in the X direction. In the optical integrated device 300, when the optical semiconductor device 100 and the optical functional device 200 are aligned as illustrated in FIG. 4, an end face 203b of the body 203 in the opposite direction of the X direction and the end face 11c of the optical semiconductor device 100 in the X direction are facing each other, and the active layer 11a and the core 203a are facing each other in the X direction and are lined up in the X direction. On the end face 11c, the laser light output from the active layer 11a undergoes coupling with the core 203a and gets transmitted inside the core 203a. Herein, the X direction represents an example of a third direction.

In such a configuration, if the active layer 11a and the core 203a are misaligned in the Z direction, there occurs a decline in the coupling efficiency of the light between the active layer 11a and the core 203a. In that regard, in the first embodiment, for example, a distance δ1 between the center of the active layer 11a in the Z direction and the end portion 12a of each second protrusion 12 can be matched with a distance δ2 between the center of the core 203a in the Z direction and the end portion 202a of the protrusion 202 in the opposite direction of the Z direction, and accordingly the active layer 11a and the core 203a can be aligned in the Z direction.

As explained earlier, in the first embodiment, the mesa 21 included in the first protrusion 11 and the mesa 22 included in each second protrusion 12 have the same laminate structure in which a plurality of semiconductor layers are layered. Hence, by managing the layer thickness of the semiconductor layers during the manufacturing process (the crystalline growth process) of the mesas 21 and 22, the distance δ1 can be set with more ease and with more accuracy as the distance δ1 in the Z direction between the center of the third layer 20c, which functions as the active layer 11a in the mesa 21, in the Z direction and the end portion 12a of the sixth layer 20f, which serves as the end portion 12a in the mesa 22 (the second protrusion 12), in the Z direction, as illustrated in FIG. 1. Moreover, as is the case in the first embodiment, when the end portion 12a of the second protrusion 12 is not covered by some other layer such as a passivation film, there is no decline in the alignment accuracy in the Z direction that might occur due to the variation or the peeling off of the film thickness of such other layer. Hence, according to the first embodiment, as compared to the conventional configuration, the optical semiconductor device 100 and the optical functional device 200 can be aligned with more ease and with more accuracy in the Z direction, that is, in the layering direction of the semiconductor layers in the optical semiconductor device 100; and any decline in the coupling efficiency of the light can be held down.

Meanwhile, in the first embodiment, the optical semiconductor device 100 includes a plurality of second protrusions 12. Moreover, the first protrusion 11 is positioned in between a plurality of second protrusions 12. With such a configuration, the optical semiconductor device 100 can be supported with greater stability because of a plurality of second protrusions 12.

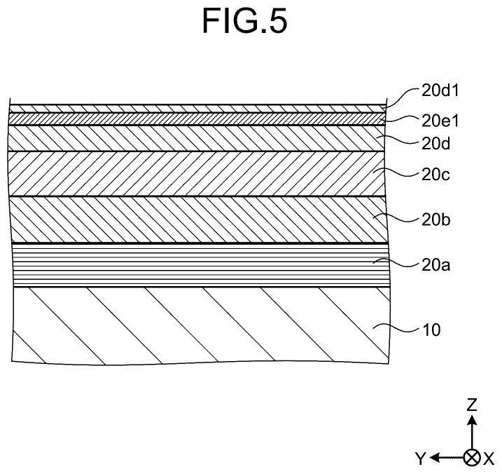

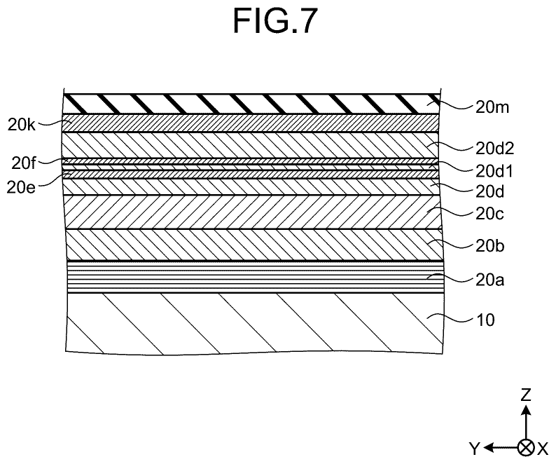

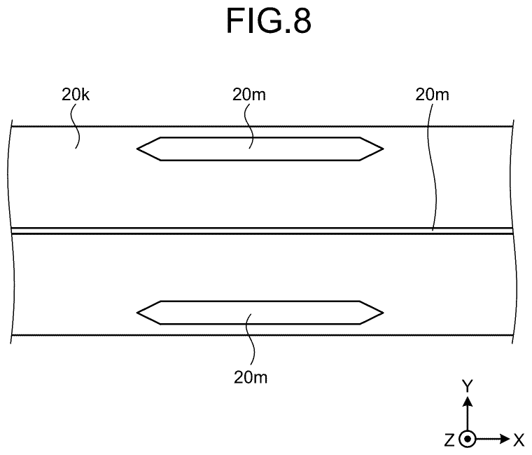

FIGS. 5 to 11 are diagrams illustrating the intermediate product materials obtained during each manufacturing process in the manufacturing method for the optical semiconductor device 100. FIGS. 5 to 7 and FIGS. 9 to 11 are cross-sectional views of the product materials. FIG. 8 is a planar view of the product material obtained at the same stage as the stage illustrated in FIG. 7. Herein, a product material can also be referred to as a laminate structure.

Firstly, as illustrated in FIG. 5, on the face 10a of the substrate 10 representing a wafer, the following layers are formed by means of crystalline growth: the first layer 20a; the second layer 20b; the third layer 20c; the fourth layer 20d; a layer 20e1 responsible for the first parts of the diffraction grating layer 11b; and the layer 20d1 formed on the diffraction grating layer 11b. The layer 20e1 is made of p-InGaAsP. The third layer 20c that functions as the active layer 11a in the mesa 21 represents an example of a third semiconductor layer.

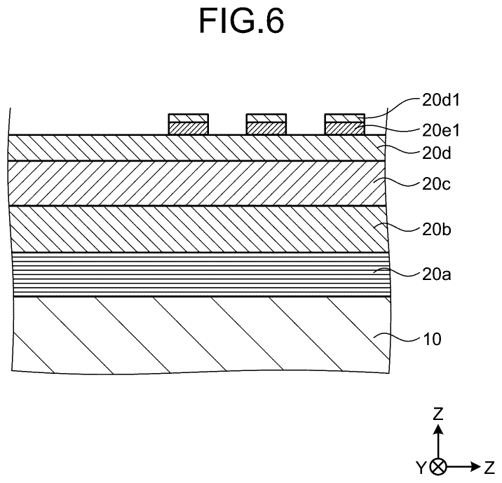

Then, as illustrated in FIG. 6, etching is performed on the product material illustrated in FIG. 5, and the layers 20e1 and 20d1 are selectively removed at intervals in the X direction. Subsequently, the removed portions are filled with p-InP. It results in the formation of the fifth layer 20e, which functions as the diffraction grating layer 11b in the mesa 21, and in the formation of the layer 20d1 on the fifth layer 20e.

Then, as illustrated in FIG. 7, on the layer 20d1 that is formed on the fifth layer 20e; the sixth layer 20f, the layer 20d2, a sacrificial layer 20k, and a mask layer 20m are formed. The sacrificial layer 20k is, for example, made of InGaAsP; and the mask layer 20m is, for example, made of SiN. The mask layer 20m formed in FIG. 7 is shaped to have a planar shape as illustrated in FIG. 8.

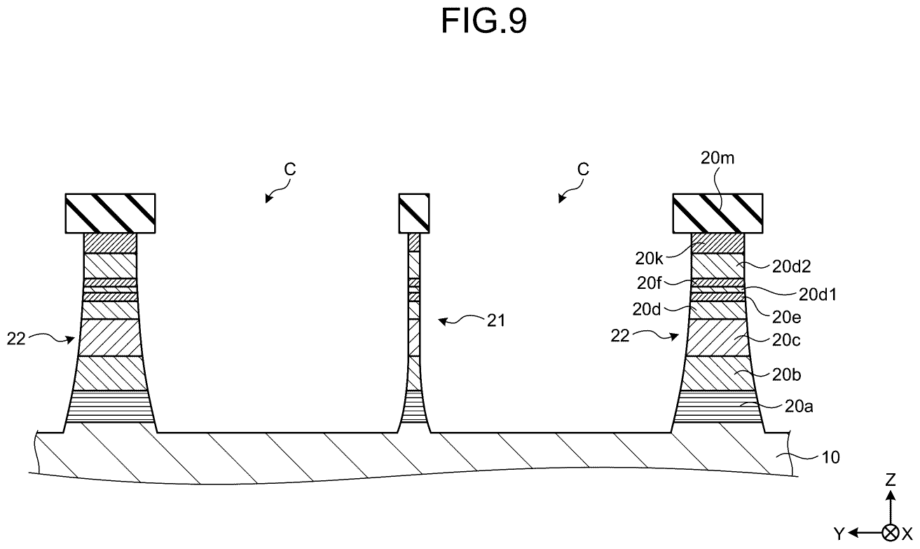

Subsequently, as illustrated in FIG. 9, from the product material illustrated in FIG. 7, the part that is not covered by the mask layer 20m is removed by means of etching. As a result, concave portions C, the mesa 21, and the mesas 22 are formed on the opposite side in the Z direction with respect to the mask layer 20m and the sacrificial layer 20k. That is, in the product material illustrated in FIG. 7, as a result of partial removal on the opposite side of the substrate 10, a plurality of mesas 21 and 22 is formed on the substrate 10, and the concave portions C are formed in between the mesas 21 and 22. Meanwhile, at the time of performing etching, the sacrificial layer 20k assumes the role of adjusting the lateral-face shape of the mesas 21 and 22 to be gentle curved surfaces running along the Z direction.

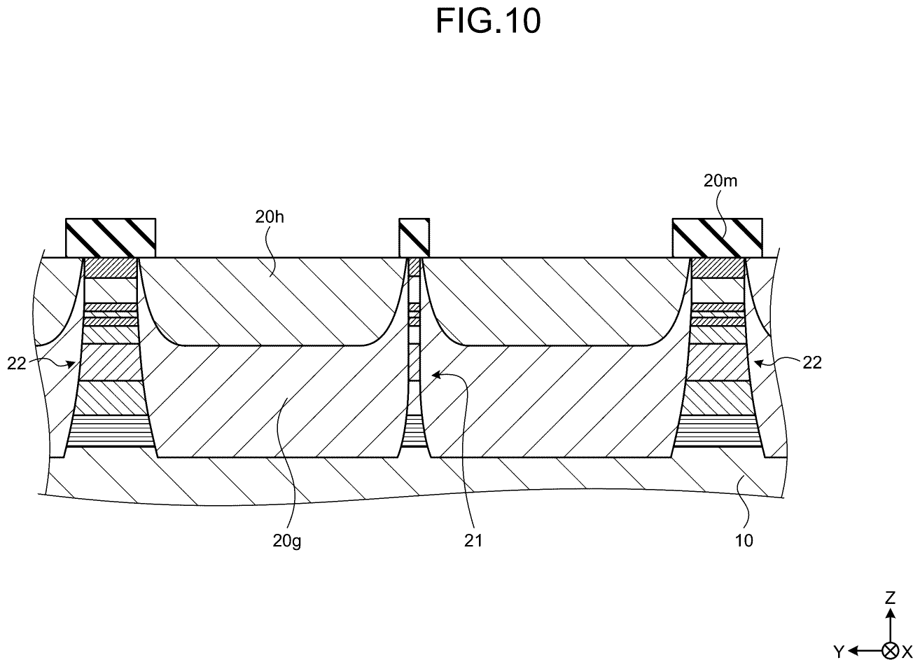

Then, as illustrated in FIG. 10, the current inhibition layers 20g and 20h are formed to fill the concave portions C (see FIG. 9) present between the mesas 21 and 22.

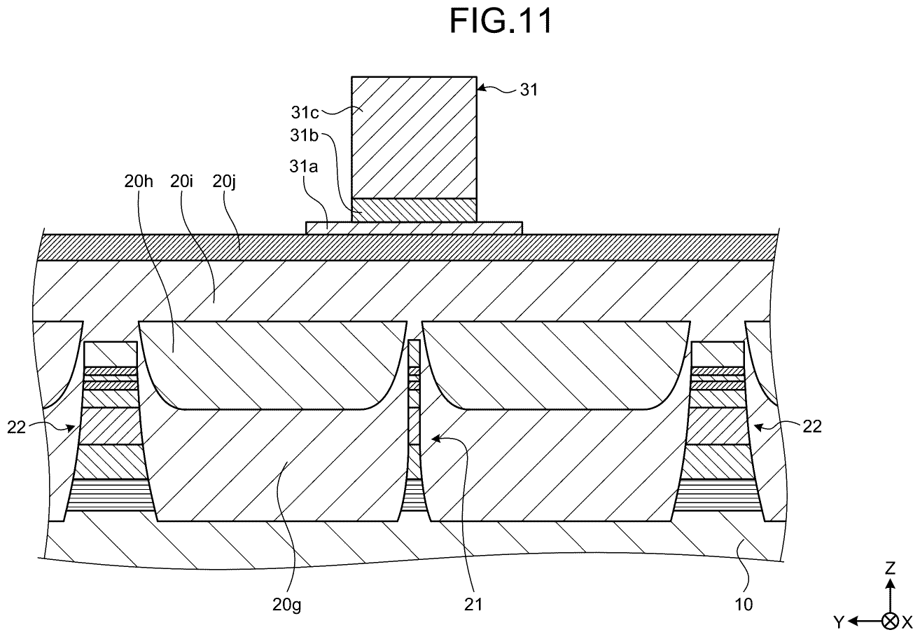

Subsequently, as illustrated in FIG. 11, the mask layer 20m and the sacrificial layer 20k are removed from the product material illustrated in FIG. 10; and the cladding layer 201, the contact layer 20j, the base layer 31a, the barrier layer 31b, and the thick-film layer 31c are layered on the opposite side of the substrate 10 in the product material. Herein, the contact layer 20j, the base layer 31a, the barrier layer 31b, and the thick-film layer 31c represent examples of a conductor layer.

Subsequently, from the product material illustrated in FIG. 11, the part that is present on the opposite side of the substrate 10 and between the mesa 21 and the mesas 22 is removed by means of etching using a predetermined etching solution or a predetermined etching gas; and, as illustrated in FIG. 1, the first protrusion 11 including the mesa 21 (but without the insulating film 20n) is formed, and the second protrusions 12 representing the mesas 22 are formed. The first protrusion 11 includes the mesa 21; includes that part from among the current inhibition layers 20g and 20h, the cladding layer 20i, and the contact layer 20j which is adjacent to the mesa 21 (i.e., the surrounding part of the mesa 21 that covers the mesa 21); and includes the electrode 31.

At the time of performing such etching, in each mesa 22 (the second protrusion 12), the sixth layer 20f functions as the etch stop layer and becomes exposed in the end portion 12a in the Z direction of the second protrusion 12. In the first embodiment, the sixth layer 20f represents an example of a fourth semiconductor layer.

Then, after the end face of the substrate 10 in the opposite direction of the Z direction is polished and the face 10b is formed, the electrode 32 is formed on the face 10b using, for example, the vapor-deposition liftoff technique. Subsequently, for example, heat treatment is performed at about 400° C., and ohmic connection is established among the electrode 31, the electrode 32, and the semiconductor layers of the first protrusion 11. Moreover, the lateral faces of the first protrusion 11 are covered by the insulating film 20n.

The wafer (not illustrated) that has been subjected to the abovementioned processing is cleaved. Then, low-reflectivity coating is performed on the end face 11c in the X direction (see FIG. 2), and high-reflectivity coating is performed on the end face 11d in the opposite direction of the X direction. As a result, the optical semiconductor device 100 illustrated in FIGS. 1 and 2 reaches completion.

As explained above, according to the structure and the method explained in the first embodiment, regarding the optical semiconductor device 100 and the optical functional device 200; in the Z direction, that is, in the direction of layering the semiconductor layers in the optical semiconductor device 100, alignment can be achieved with more ease and with more accuracy. In turn, a decline in the coupling efficiency of the light between the optical semiconductor device 100 and the optical functional device 200 can be held down with more ease and in a more reliable manner. That is, according to the first embodiment, it becomes possible to provide the optical semiconductor device 100 in a new and improved form, and to provide the optical integrated device 300 and a manufacturing method for the optical semiconductor device 100.

Moreover, in the optical integrated device 300 according to the first embodiment, the height of the second protrusions 12 in the Z direction is lower than the height of the first protrusion 11 in the Z direction, and the end portions 12a of the second protrusions 12 of the optical semiconductor device 100 come in contact with the end portions 202a of the protrusions 202 of the optical functional device 200. If the configuration is such that, between the optical semiconductor device 100 and the optical functional device 200, alignment is achieved when the protrusions of one device and the depressed portions of the other device come in contact, the device for the depressed portions needs to include a peripheral wall on which the depressed portions can be formed for housing the protrusions of the other device. Thus, in the part that gets aligned, the protrusions and the depressed portions overlap in a direction intersecting with the direction of protrusion (the layering direction). Hence, there is a risk that the device having the depressed portions increases in size in the direction intersecting with the direction of protrusion. In that regard, the optical integrated device 300 according to the first embodiment has a structure in which the second protrusions 12 come in contact with the protrusions 202. Accordingly, as compared to a configuration in which the protrusions and the depressed portions are aligned, it becomes possible to achieve a more compact configuration.

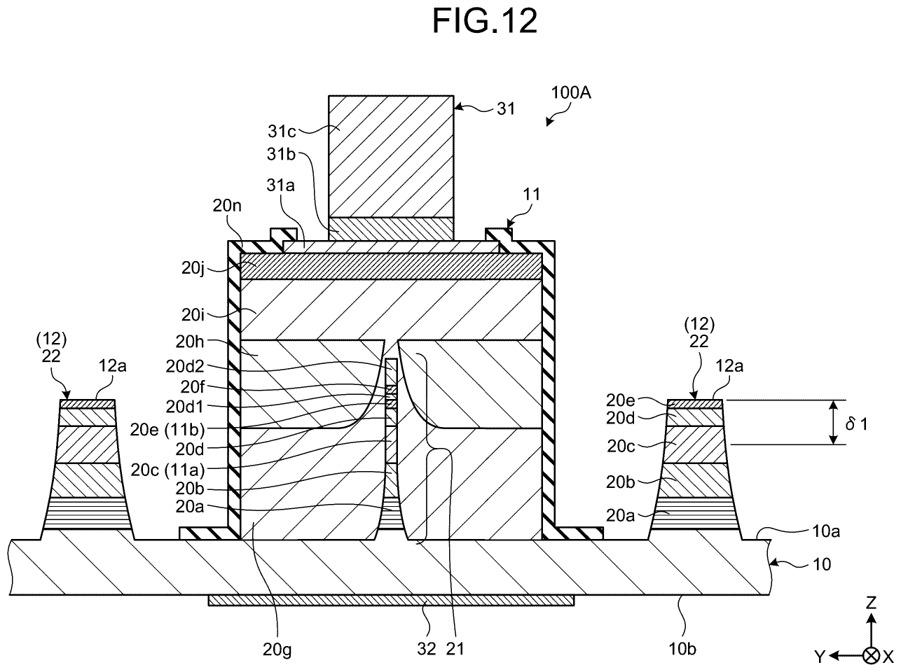

FIG. 12 is a cross-sectional view of an optical semiconductor device 100A according to a second embodiment. The optical semiconductor device 100A according to the second embodiment has an identical configuration to the optical semiconductor device 100 according to the first embodiment, except for having a different cross-sectional shape.

As illustrated in FIG. 12, in the second embodiment, on the end portion 12a of each second protrusion 12, the fifth layer 20e functioning as the diffraction grating layer 11b in the mesa 21 becomes exposed. The fifth layer 20e too is, what is called, a quaternary layer capable of functioning as an etch stop layer having the property of neither being etchable by a predetermined etching solution nor being etchable by a predetermined etching gas used in the etching of other semiconductor layers. Thus, as explained in the second embodiment, the fifth layer 20e functioning as the diffraction grating layer 11b in the mesa 21 can be treated as the end portion 12a of the corresponding second protrusion 12. In the second embodiment, the fifth layer 20e of the mesa 21 represents an example of a first semiconductor layer, and the fifth layer 20e of each mesa 22 represents an example of a second semiconductor layer. Moreover, the fifth layer 20e represents an example of the fourth semiconductor layer.

According to the second embodiment too, it is possible to achieve identical effects to the effects achieved according to the first embodiment. Moreover, according to the second embodiment, in each mesa 22, the distance 81 from the third layer 20c, which serves as the active layer 11a in the mesa 21, to the corresponding end portion 12a can be set to be shorter. That enables achieving reduction in the effect exerted on the distance 81 due to the variation in the thickness of the semiconductor layers positioned on the opposite side of the substrate 10 with respect to the third layer 20c. In turn, sometimes it becomes possible to further hold down a decline in the coupling efficiency of the light.

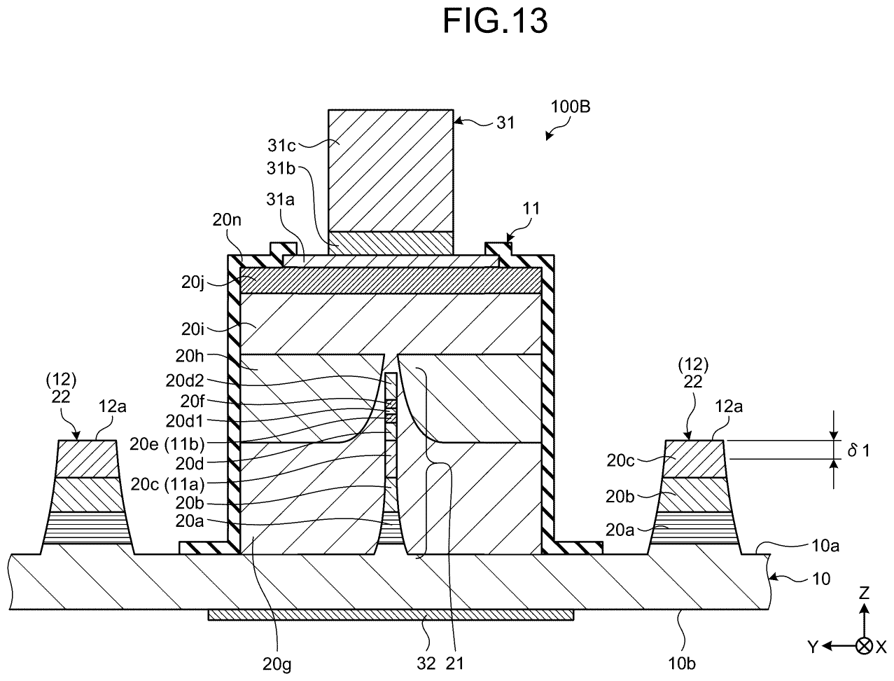

FIG. 13 is a cross-sectional view of an optical semiconductor device 100B according to a third embodiment. The optical semiconductor device 100B according to the third embodiment has an identical configuration to the optical semiconductor device 100 according to the first embodiment, except for having a different cross-sectional shape.

As illustrated in FIG. 13, in the third embodiment, on the end portion 12a of each second protrusion 12, the third layer 20c functioning as the active layer 11a in the mesa 21 becomes exposed. The third layer 20c too is, what is called, a quaternary layer capable of functioning as an etch stop layer having the property of neither being etchable by a predetermined etching solution nor being etchable by an etching gas used in the etching of other semiconductor layers. Thus, as explained in the third embodiment, the third layer 20c functioning as the active layer 11a in the mesa 21 can be treated as the end portion 12a of the corresponding second protrusion 12.

According to the third embodiment too, it is possible to achieve identical effects to the effects achieved according to the first embodiment. Moreover, according to the third embodiment, in each mesa 22, the distance 81 from the third layer 20c, which serves as the active layer 11a in the mesa 21, to the corresponding end portion 12a can be set to be shorter. That enables achieving reduction in the effect exerted on the distance 81 due to the variation in the thickness of the semiconductor layers positioned on the opposite side of the substrate 10 with respect to the third layer 20c. In turn, sometimes it becomes possible to further hold down a decline in the coupling efficiency of the light.

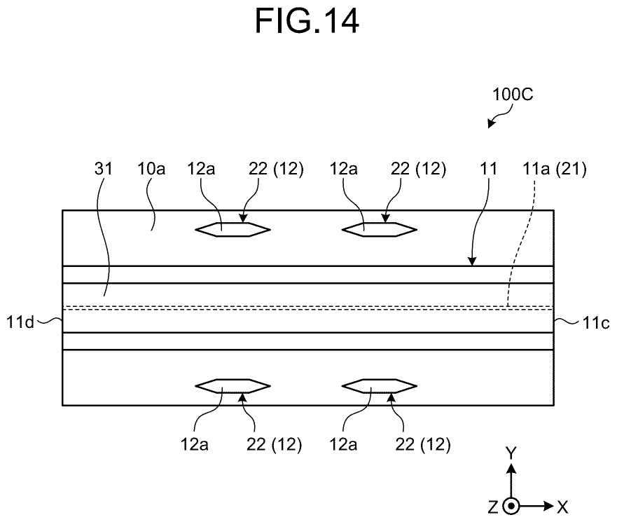

FIG. 14 is a planar view of an optical semiconductor device 100C according to a fourth embodiment. The optical semiconductor device 100C according to the fourth embodiment has an identical configuration to the optical semiconductor device 100 according to the first embodiment, except for having a different shape and a different arrangement of the second protrusions 12.

As illustrated in FIG. 14, in the fourth embodiment, on each side of the first protrusion 11 in the Y direction, two second protrusions 12 are disposed at a distance from each other in the X direction. In such a configuration too, it is possible to achieve identical effects to the effects achieved according to the first embodiment. Moreover, according to the fourth embodiment, since the second protrusions 12 can be configured to be smaller in size, the optical semiconductor device 100 can be further reduced in weight. Meanwhile, the optical functional device 200 either can be configured to include the same number of protrusions 202 as the number of second protrusions 12, so as to have a one-to-one correspondence; or can be configured to include a smaller number of protrusions 202 than the number of second protrusions 12, so as to have a one-to-many correspondence. Moreover, it is desirable that the centers in the X direction of the two second protrusions 12 arranged in the X direction are separated from each other by a distance equal to or greater than one-third of the length of the optical semiconductor device 100.

According to the present disclosure, it becomes possible to provide a new and improved optical semiconductor device and to provide an optical integrated device and a manufacturing method for the optical semiconductor device.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An optical semiconductor device comprising:
a substrate;
a first protrusion protruding from the substrate in a first direction and including a first mesa having a laminate structure in which a plurality of semiconductor layers are layered on the substrate in the first direction, the first mesa including an active layer as one of the semiconductor layers; and
a second protrusion protruding from the substrate in the first direction at a distance from the first protrusion in a second direction intersecting with the first direction, the second protrusion having a same laminate structure as the laminate structure of the first mesa, wherein one of the plurality of semiconductor layers is exposed at an end portion of the second protrusion in the first direction.

2. The optical semiconductor device according to claim 1, wherein a plurality of second protrusions are included as the second protrusion.

3. The optical semiconductor device according to claim 2, wherein the first protrusion is positioned between the plurality of second protrusions.

4. The optical semiconductor device according to claim 1, wherein
the first mesa includes, as the one of the semiconductor layers, a first semiconductor layer positioned on an opposite side of the substrate with respect to the active layer, the first semiconductor layer being neither etchable by a predetermined etching solution nor etchable by a predetermined etching gas which are capable of etching other semiconductor layers, or having a sufficiently small etching rate than the other semiconductor layers, and
the second protrusion includes, as the one of the semiconductor layers, a second semiconductor layer made of same material as the first semiconductor layer, the second semiconductor layer being exposed at the end portion of the second protrusion in the first direction and lined up with the first semiconductor layer in the second direction.

5. The optical semiconductor device according to claim 4, wherein the first semiconductor layer is a diffraction grating layer.

6. The optical semiconductor device according to claim 1, wherein the second protrusion includes, as the one of the semiconductor layers, a second semiconductor layer exposed at the end portion of the second protrusion in the first direction, made of same material as the active layer and lined up with the active layer in the second direction.

7. An optical integrated device comprising:
an optical functional device including an optical waveguide having a core; and
the optical semiconductor device according to claim 1, wherein
the optical functional device includes a contact portion positioned on an opposite side of the substrate with respect to the second protrusion,
the optical functional device makes contact with the second protrusion, and
the core and the active layer are facing toward a third direction intersecting with the first direction.

8. The optical integrated device according to claim 7, wherein
the optical functional device includes a base, and
the contact portion is provided on a third protrusion protruding from the base in an opposite direction of the first direction.

9. The optical integrated device according to claim 8, wherein
the optical semiconductor device includes a first electrode positioned at a distance from the active layer in the first direction,
the optical functional device includes a second electrode disposed on the base, and
the first electrode and the second electrode are electrically connected to each other.

10. A manufacturing method for an optical semiconductor device, comprising:
forming, on a substrate, a laminate structure in which a plurality of semiconductor layers are layered in a first direction, the plurality of semiconductor layers including
a third semiconductor layer made of material functioning as an active layer, and
an etch stop layer that is neither etchable by a predetermined etching solution nor etchable by a predetermined etching gas which are capable of etching other semiconductor layers, or having a sufficiently small etching rate than the other semiconductor layers, the etch stop layer being either a fourth semiconductor layer formed on an opposite side of the substrate with respect to the third semiconductor layer, or the third semiconductor layer;
forming a plurality of mesas protruding from the substrate at a plurality of locations separated in a second direction intersecting with the first direction by partially removing the laminate structure on an opposite side of the substrate;
forming a current inhibition layer in order to fill spaces among the plurality of mesas;
forming a conductor layer on the opposite side of the substrate with respect to the third semiconductor layer;
forming a first protrusion including
a first mesa that is one of the plurality of mesas,
a part of the current inhibition layer that is adjacent to the first mesa, and
a part of the conductor layer that is present on an opposite side of the substrate with respect to the first mesa; and
forming a second mesa that is one of the plurality of mesas other than the first mesa by performing etching using the predetermined etching solution or the predetermined etching gas such that the etch stop layer included in the second mesa becomes exposed at an end portion in the first direction.
